(19) United States
(12) Patent Application Publication
(10) Pub. No.: US 2012/0155052 A1
(43) Pub. Date: Jun. 21, 2012

(54) ELECTRONIC DEVICE HOUSING AND MANUFACTURING METHOD THEREOF

(75) Inventors: FA-GUANG SHI, Shenzhen City (CN); JING-HUA YUAN, Shenzhen City (CN)

(73) Assignees: HON HAI PRECISION INDUSTRY CO., LTD., Tu-Cheng (TW); FU TAI HUA INDUSTRY (SHENZHEN) CO., LTD., ShenZhen City (CN)

(21) Appl. No.: 13/152,412

(22) Filed: Jun. 3, 2011

(30) Foreign Application Priority Data
Dec. 20, 2010 (CN) 201010596203.3

(51) Int. Cl. H05K 7/00; B23P 13/00; B23P 17/00

(52) U.S. Cl. 361/807; 29/527.6; 72/340

(57) ABSTRACT

An electronic device includes a bottom housing and a display panel. The bottom housing includes a bottom wall, a side wall, a support plate, and a plurality of reinforcement portions. The side wall extends from an edge of the bottom wall. The support plate extends toward a center of the bottom housing from a top end of the side wall, and defines an assembly groove. The side wall includes a plurality of side plates connecting with each other. The reinforcement portions are positioned at the corners of the bottom housing Each of the reinforcement portions is sandwiched between the bottom wall and the support plate, and connecting two adjacent side plates. A manufacturing method for an electronic device housing is also provided.

### BACKGROUND

1. Technical Field

The present disclosure relates generally to electronic devices, more particularly, to an electronic device having an integrally formed housing.

2. Description of Related Art

A typical electronic device housing includes a bottom housing and a top housing. The top housing is fixed to the bottom housing by welding, adhering or with fastening members. However, the electronic device may be dropped or fallen down on the floor sometimes, thereby causing damage to the electronic device, if a structural strength of the combined top housing and bottom housing is low. Thus, electronic devices generally employ some buffering members at the corners. The buffering members can be made of foam materials. When the electronic device is dropped or fallen down on the floor, the buffering members absorb the impact energy, thereby protecting the electronic device. However, the electronic device with the buffering members has a larger size and a poor aesthetic appearance.

Therefore, there is room for improvement within the art.

### BRIEF DESCRIPTION OF THE DRAWINGS

The components in the drawings are not necessarily drawn to scale, the emphasis instead placed upon clearly illustrating the principles of the present disclosure. Moreover, in the drawings, like reference numerals designate corresponding parts throughout the several views.

FIG. 1 is an isometric view of an embodiment of an electronic device including a bottom housing and a display panel.

FIG. 2 an exploded, isometric view of the electronic device of FIG. 1.

FIG. 3 is a partial cross-section of the electronic device of FIG. 1, taken along line III-III.

FIG. 4 is a partial cross-section of the electronic device of FIG. 1, taken along line IV-IV.

FIG. 5 is an isometric view of an original housing configured to form the bottom housing of FIG. 1.

### DETAILED DESCRIPTION

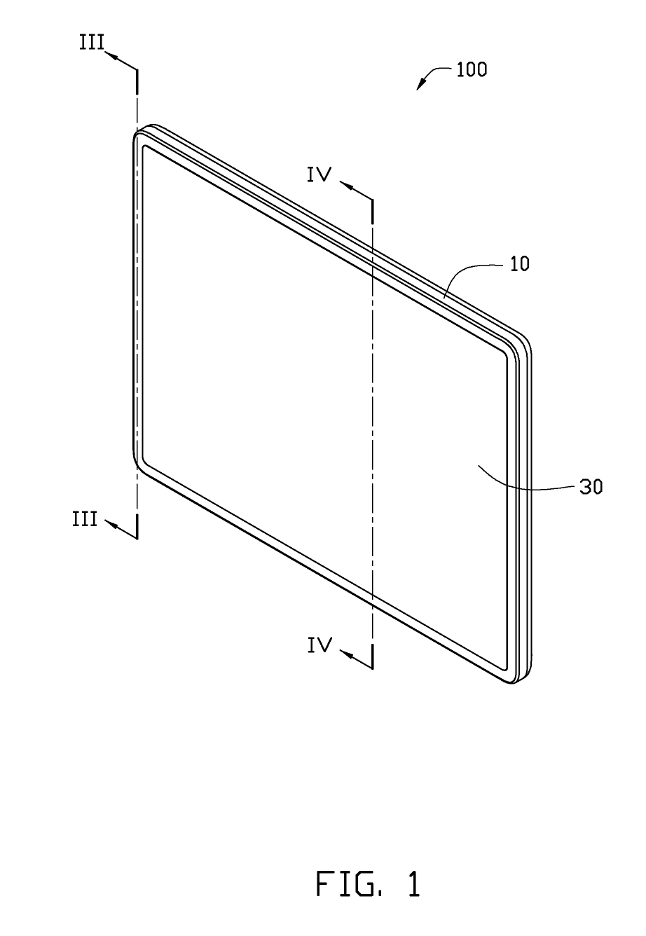

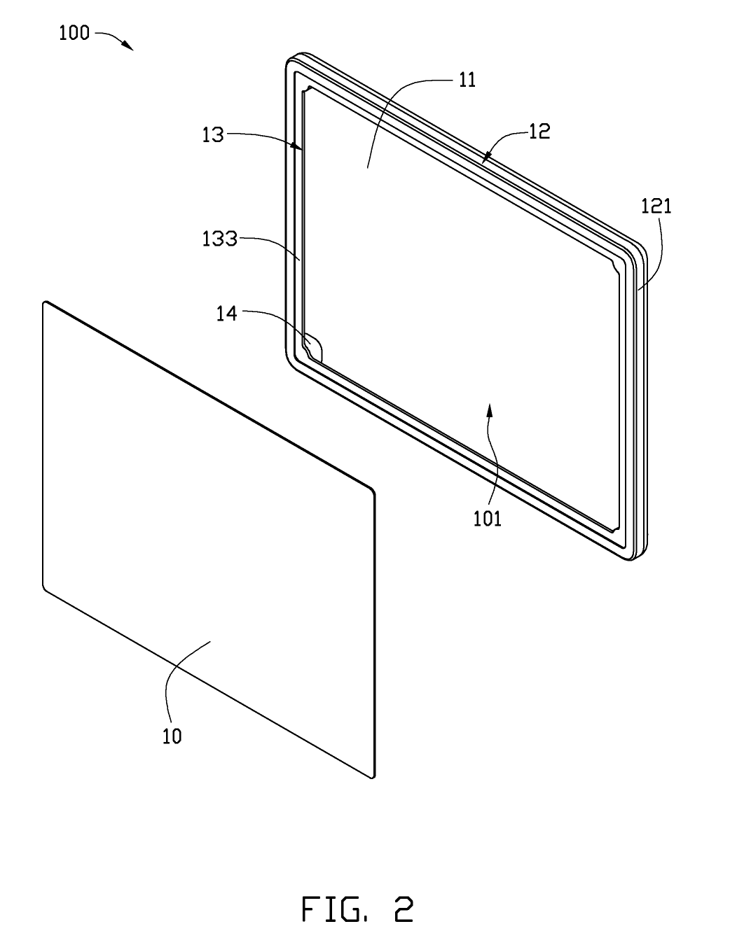

Referring to FIGS. 1 and 2, an embodiment of an electronic device 100 includes a bottom housing 10 and a display panel 30 positioned in the bottom housing 10. The electronic device 100 may be a computer, a mobile phone, or a digital photo frame. In the illustrated embodiment, the electronic device 100 is a tablet computer, and the display panel 30 is a touch panel. The bottom housing 10 is made of metal materials, such as aluminum alloy.

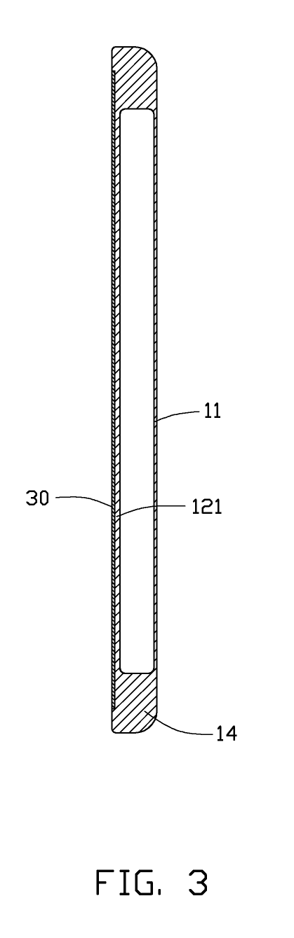

Referring also to FIG. 3, the bottom housing 10 includes a bottom wall 11, a side wall 12, a support plate 13, and a plurality of reinforcement portions 14. The side wall 12 extends from the edges of the bottom wall 11, and includes four side plates 121 connecting with each other to form a rectangular structure. The bottom wall 11 and the side wall 12 cooperatively define a receiving space 101 to receive a plurality of electrical or electronic components (not shown). The support plate 13 extend from a top end of the side wall 12 toward a center of the bottom housing 10. The support plate 13 is substantially parallel to the bottom wall 11, and defines an assembly groove 133 to receive the display panel 30. The reinforcement portions 14 are positioned at the respective corners of the bottom housing 10. Each reinforcement portion 14 is sandwiched between the bottom wall 11 and the support plate 13, and connecting two adjacent side plates 121 together. Two adjacent reinforcement portions 14 together with the bottom wall 11 and the support plate 13 cooperatively define a connecting groove 141 communicating with the receiving space 101. In the illustrated embodiment, the connecting groove 141 is substantially a U-shaped groove.

The display panel 30 is fixed in the assembly groove 133 of the support plate 13, and aligned with a top surface of the support plate 13, such that the electronic device 100 can have a better aesthetic appearance.

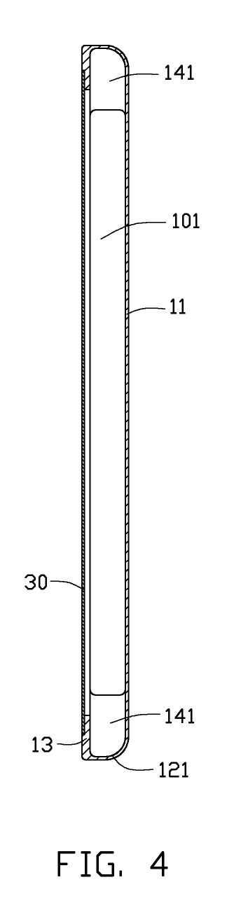

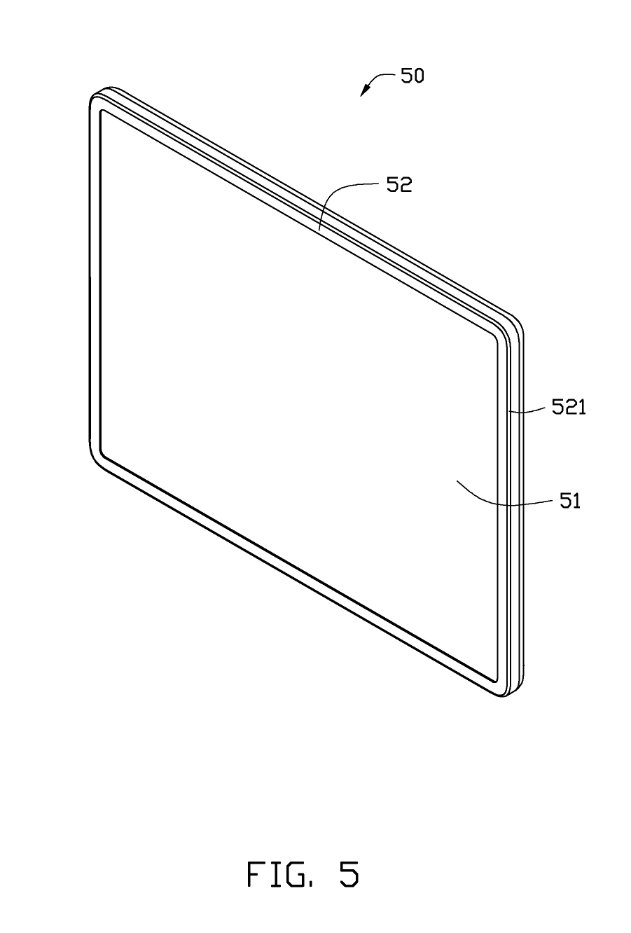

Referring to FIGS. 2 through 5, one embodiment of a manufacturing method for the bottom housing 10 is described as follows. A mold (not shown) and a metal block (not shown) is provided. The metal block is cast or forged in the mold to form an original housing 50. The original housing 50 includes a bottom wall 51 and a side wall 52 extending from an edge of the bottom wall 51, and the side wall 52 includes four side plates 521 connecting with each other to form a rectangular shaped structure. An inner surface of each side plate 521 is milled to form the support plate 13 and the reinforcement portions 14, and thereby defined the U-shaped connecting groove 141 between the support plate 13 and the reinforcement portions 14. The top surface of the support plate 13 is milled to define the assembly groove 133, such that the bottom housing 10 is formed from the original housing 50. The bottom housing 10 can undergo further machining processes, such as a polishing and coating processes, to obtain an excellent appearance.

Because the bottom housing 10 is integrally formed from the metal block, a mechanical strength of the bottom housing 10 is thereby higher. Furthermore, the metal block is cast or forged to form the original housing 50, and not punched by a punch mold, thus the mechanical strength of the bottom housing 10 formed by the original housing 50 can be further enhanced. In addition, the reinforcement portions 14 are formed at the corners of the bottom housing 10, therefore, the corners of the bottom housing 10 have a relatively high mechanical strength. When the electronic device 100 employing the bottom housing 10 is dropped or fallen down on the floor, the bottom housing 10 is more difficult to be broken, and thereby effectively protects the internal electrical or electronic components. The electronic device 100 employing the bottom housing 10 also has a smaller size and a better appearance, because the reinforcement portions 14 are integrally formed inside of the electronic device 100.

It is believed that the present embodiments and their advantages will be understood from the foregoing description, and it will be apparent that various changes may be made thereto without departing from the spirit and scope of the disclosure or sacrificing all of its material advantages.

What is claimed is:

1. An electronic device, comprising:
a bottom housing comprising a bottom wall, a side wall, and a support plate, wherein the side wall extends from the edges of the bottom wall, the support plate extends from a top end of the side wall toward a center of the bottom housing, and defines an assembly groove; and
a display panel fixedly positioned in the assembly groove of the support plate;
wherein the side wall comprises a plurality of side plates connecting with each other, the bottom housing further comprises a plurality of reinforcement portions at the corners thereof, each of the reinforcement portions is sandwiched between the bottom wall and the support plate, and connecting two adjacent side plates.

2. The electronic device housing of claim 1, wherein the support plate is substantially parallel to the bottom wall.

3. The electronic device housing of claim 1, wherein the display panel is aligned with a top surface of the support plate in a same plane.

4. The electronic device housing of claim 1, wherein two adjacent reinforcement portions together with the bottom wall and the support plate cooperatively define a connecting groove.

5. The electronic device housing of claim 4, wherein the connecting groove is substantially a U-shaped groove.

6. The electronic device housing of claim 1, wherein the side plates connecting with each other to form substantially a rectangular structure.

7. The electronic device housing of claim 1, wherein the bottom housing is a metal housing.

8. An electronic device housing, comprising:
a bottom wall;
a side wall extending from the edges of the bottom wall, the side wall comprises a plurality of side plates connecting with each other;
a support plate extending from a top end of the side wall toward a center of the electronic device housing; and
a plurality of reinforcement portions at the corners thereof, each of the reinforcement portions sandwiched between the bottom wall and the support plate, and connecting two adjacent side plates.

9. The electronic device housing of claim 8, wherein the support plate is substantially parallel to the bottom wall.

10. The electronic device housing of claim 8, wherein two adjacent reinforcement portions together with the bottom wall and the support plate cooperatively define a connecting groove.

11. The electronic device housing of claim 10, wherein the connecting groove is substantially a U-shaped groove.

12. The electronic device housing of claim 8, wherein the side plates connecting with each other to form substantially a rectangular structure.

13. The electronic device housing of claim 8 is a metal housing.

14. A method of manufacturing an electronic device housing, comprising:
casting or forging a metal block to form an original housing comprising a bottom wall and a side wall extending from the edges of the bottom wall;
milling an inner surface of the side wall to form a support plate and a plurality of reinforcement portions between the support plate and the bottom wall.

15. The method of claim 14, further comprising the step of milling the support plate to define an assembly groove.

16. The method of claim 14, wherein the reinforcement portions are formed at the corners of the electronic device housing.
